(19) United States
(12) Patent Application Publication
(10) Pub. No.: US 2019/0146231 A1
(43) Pub. Date: May 16, 2019

(54) CURVED STEREOSCOPIC IMAGE DISPLAY DEVICE AND MANUFACTURING METHOD THEREOF

(71) Applicant: KORTEK CORPORATION, INCHEON (KR)

(72) Inventor: KYOUNG CHAN LEE, SEOUL (KR)

(21) Appl. No.: 16/315,850

(22) PCT Filed: Jul. 12, 2017
(86) PCT No.: PCT/KR2017/007434

§ 371 Date: Jan. 7, 2019

(30) Foreign Application Priority Data
Jul. 12, 2016 (KR) 10-2016-0087990

(51) Int. Cl. G02B 27/22; G06F 1/16; H04N 13/30; H05K 3/00

(52) U.S. Cl. CPC G02B 27/2214; G06F 1/16; H05K 2201/09018; H05K 3/0014; H04N 13/30

(57) ABSTRACT

A curved stereoscopic image display device and a manufacturing method thereof is provided. The curved stereoscopic image display apparatus includes: a glass part which forms a curved surface and to which an image is transmitted; a lens part which is attached to a lateral side of the glass part, forms a lens or a barrier, and implements a stereoscopic image; and a panel part to which the glass part is attached. The lens part is formed on the lateral side of the glass part while a coating material outside a rolling forming part which is rotatably installed is in contact with the lateral side of the glass part. The disclosed embodiments can improve productivity by reducing a production process

### CROSS-REFERENCE TO RELATED APPLICATIONS

This application claims priority to PCT Application No. PCT/KR2017/007434, having a filing date of Jul. 12, 2017, based on KR 10-2016-0087990, having a filing date of Jul. 12, 2016, the entire contents both of which are hereby incorporated by reference.

### FIELD OF TECHNOLOGY

The following relates to a curved stereoscopic image display device and manufacturing method thereof, and more particularly, to a curved stereoscopic image display device and manufacturing method thereof in which a lens or a barrier is directly formed on curved glass so that productivity can be increased as compared with a method in which a film is attached.

### BACKGROUND

Generally, using the principle of stereo vision through both eyes, a three-dimensional stereoscopic image may cause a cubic effect to be felt by both eyes due to binocular disparity which is caused by a gap between the both eyes which are spaced about 65 mm apart from each other. When two-dimensional images viewed by left and right eyes of the human body are transmitted to the brain through the retina, the brain fuses the images with each other such that a sense of depth and a sense of realness of a three-dimensional image are sensed. Such a phenomenon is referred to as stereography.

In order to reproduce a stereoscopic image using stereography, a stereoscopic image display method using special glasses, a non-glass type stereoscopic image display method, a holographic display method, and the like are used.

The non-glass type stereoscopic image display method may be classified into a parallax barrier method in which a vertical lattice-shaped aperture is disposed in each image corresponding to a left eye and a right eye so that the images may be observed separately, a lenticular method using a lenticular plate in which semi-cylindrical lenses are arranged, and the like.

A stereoscopic image reproduction device using the parallax barrier method realizes a stereoscopic image by separately displaying stereo images for the left eye and the right eye. By simply causing slit type apertures, which are arranged in a vertical or horizontal direction, to overlap with a planar image on which image information for the left eye or right eye is displayed, sufficient disparity information which is sufficient for a person to sense the disparity may be provided to a user, and stereography of the user may be caused such that the user feels the cubic effect.

Conventionally, a task of installing a film, which has a three-dimensional lens or a barrier implemented thereon, on a panel is required in order to implement a curved stereoscopic image display device. However, since the film does not remain fixed, there is a difficulty in an assembly task. Therefore, there is a need to improve this.

The known art has been disclosed in Korean Unexamined Patent Application Publication No. 2016-0051404 (Date of Publication: May 11, 2016, Title: Non-glass type stereoscopic image display device and driving method thereof).

### SUMMARY

An aspect relates to a curved stereoscopic image display device and manufacturing method thereof in which a lens or a barrier is directly formed on curved glass so that productivity can be increased as compared with a method in which a film is attached.

A curved stereoscopic image display device according to embodiments of the present invention includes a glass part configured to form a curved surface and through which an image is transmitted, a lens part attached to a side of the glass part and configured to form a lens or a barrier and implement a stereoscopic image, and a panel part to which the glass part is attached, wherein the lens part is formed at the side of the glass part as a coating material at an outer portion of a rolling part, which is installed to be rotatable, abuts the side of the glass part.

The rolling part may include a rolling body formed in a cylindrical shape and configured to have a coating material applied on an outer portion thereof and a rotation support shaft configured to protrude toward both sides of the rolling body and rotate together with the rolling body.

The curved stereoscopic image display device may further include a guide rotation part installed to be rotatable at a position facing the rolling body and configured to have the glass part seated on an outer portion thereof, wherein the guide rotation part rotates in a direction opposite to the rolling body.

A manufacturing method of a curved stereoscopic image display device according to embodiments of the present invention includes a first forming operation of applying a coating material to an outer portion of a rolling part which rotates, a rotating operation of installing a glass part is at a position facing the rolling part and rotating the glass part in a direction opposite to a rotating direction of the rolling part, a second forming operation of adhering the coating material to the glass part which is in contact with the outer portion of the rolling part while rotating, a hardening operation of hardening the coating material on a side of the glass part, and an assembly operation of assembling the glass part to a panel part while a lens part is formed at the side of the glass part.

The glass part may form a curved surface, and an image may be transmitted through the glass part.

In the rotating operation, the glass part may be mounted on an outer portion of a guide rotation part, which is formed in a cylindrical shape, and abut the outer portion of the rolling part while rotating together with the guide rotation part.

In the hardening operation, the coating material adhered to the glass part may hardened by being irradiated with ultraviolet (UV) rays to form the lens part.

In a curved stereoscopic image display device and manufacturing method thereof according to embodiments of the present invention, since a lens part is formed at a side of a curved glass part and then a curved lens part is coupled to a curved panel part, a production process is shortened, and thus productivity can be increased.

### BRIEF DESCRIPTION

Some of the embodiments will be described in detail, with reference to the following figures, wherein like designations denote like members, wherein:

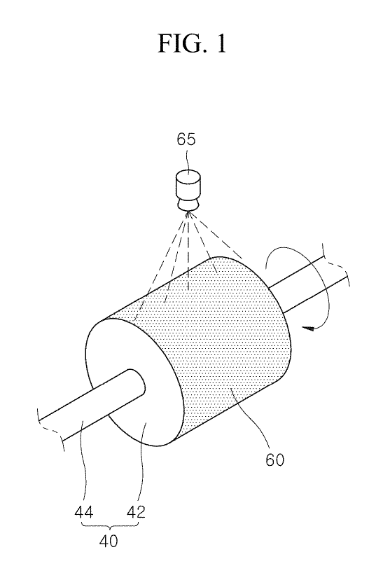

FIG. 1 is a perspective view schematically illustrating a state in which a coating material is applied on an outer portion of a rolling body according to an embodiment of the present invention;

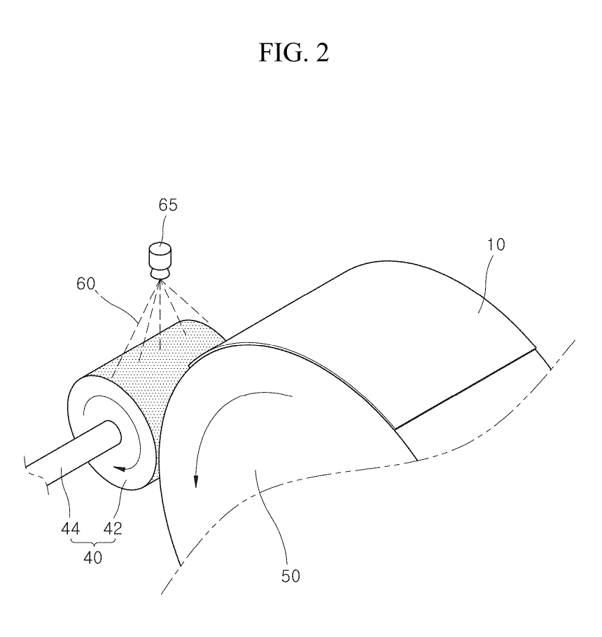

FIG. 2 is a perspective view illustrating a state in which a glass part is rotated while being mounted on the outer portion of the rolling body according to an embodiment of the present invention;

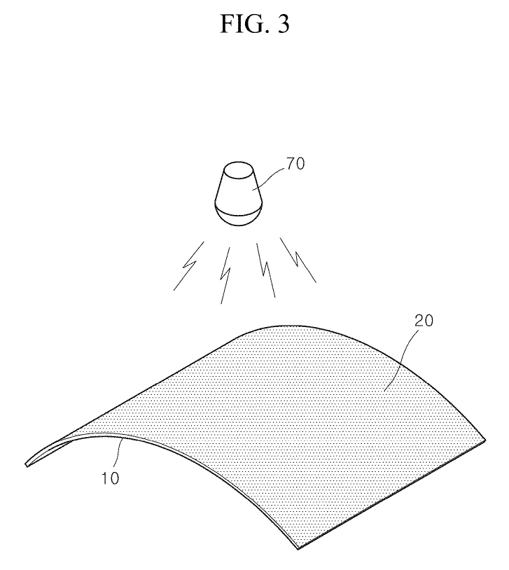

FIG. 3 is a perspective view illustrating a state in which the coating material is hardened by being irradiated with rays while the coating material is adhered to a side of the glass part according to an embodiment of the present invention;

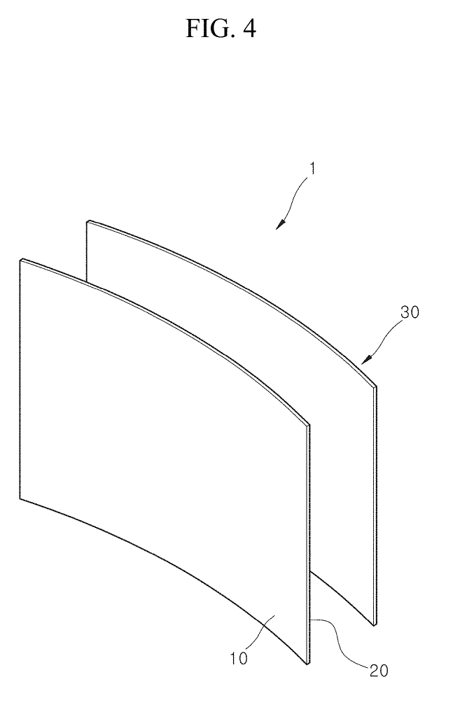

FIG. 4 is a perspective view illustrating a state in which the glass part having a lens part is disposed in front of a panel part according to an embodiment of the present invention;

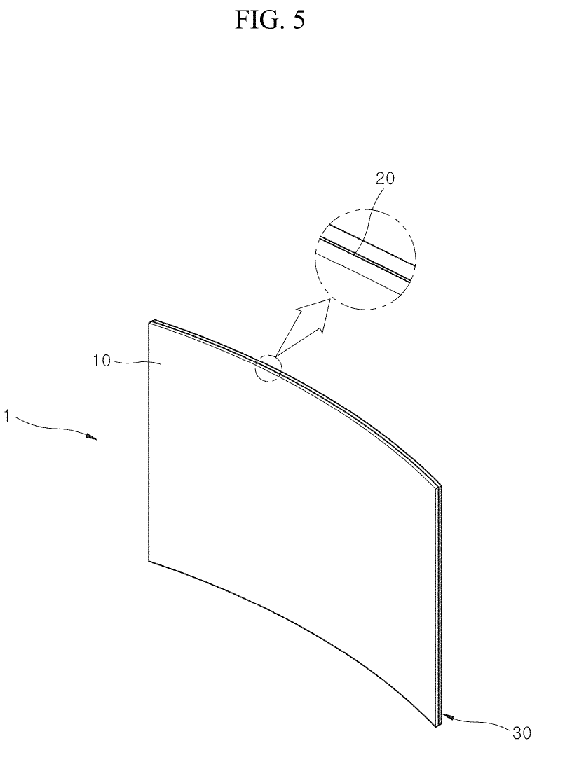

FIG. 5 is a perspective view illustrating a state in which the glass part, which is curved, is coupled to the panel part, which is curved, according to an embodiment of the present invention and

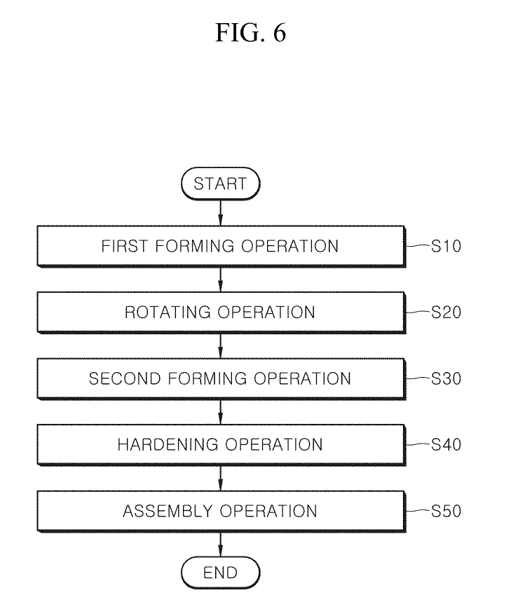

FIG. 6 is a flowchart illustrating a manufacturing method of a curved stereoscopic image display device according to an embodiment of the present invention.

### DETAILED DESCRIPTION

Hereinafter, a curved stereoscopic image display device and manufacturing method thereof according to an embodiment of the present invention will be described with reference to the accompanying drawings. In this process, thicknesses of lines, sizes of elements, or the like illustrated in the drawings may have been exaggerated for clarity and convenience of description.

Terms which will be described below are terms defined in consideration of functions in embodiments of the present invention and may vary according to intensions or practices of a user or an operator. Therefore, such terms should be defined on the basis of content throughout the present specification.

FIG. 1 is a perspective view schematically illustrating a state in which a coating material is applied on an outer portion of a rolling body according to an embodiment of the present invention; FIG. 2 is a perspective view illustrating a state in which a glass part is rotated while being mounted on the outer portion of the rolling body according to an embodiment of the present invention; FIG. 3 is a perspective view illustrating a state in which the coating material is hardened by being irradiated with rays while the coating material is adhered to a side of the glass part according to an embodiment of the present invention; FIG. 4 is a perspective view illustrating a state in which the glass part having a lens part is disposed in front of a panel part according to an embodiment of the present invention; and FIG. 5 is a perspective view illustrating a state in which the glass part, which is curved, is coupled to the panel part, which is curved, according to an embodiment of the present invention.

As illustrated in FIGS. 4 and 5, a curved stereoscopic image display device 1 according to an embodiment of the present invention includes a glass part 10 configured to form a curved surface and through which an image is transmitted, a lens part 20 attached to a side of the glass part 10 and configured to form a lens or a barrier and implement a stereoscopic image, and a panel part 30 on which the glass part 10 is mounted, wherein the lens part 20 is formed at the side of the glass part 10 as a coating material 60 outside a rolling part 40, which is installed to be rotatable, comes in contact with the side of the glass part 10.

The glass part 10 is a portion of the curved stereoscopic image display device 1 through which an image is transmitted. The glass part 10 is formed in a curved shape in order to widen a viewing angle. The glass part 10 which is formed to have a predetermined curvature is bent in a concave shape in a direction toward a viewer.

The glass part 10 may be formed in a bent shape or a flat shape and may be deformed to various shapes as necessary.

The lens part 20 is attached to a side of the glass part 10 and forms the lens or the barrier for a stereoscopic image. In a 3D mode, a function of the lens in which a path of incident light is changed in order to respectively provide different two-dimensional images to a left eye and a right eye is required. The lens part 20 according to an embodiment of the present invention performs such a function of the lens.

The lens part 20 may be formed in various shapes and may be formed as a plurality of convex lens on a surface of the glass part 10. The lens part 20 serves to distribute images to the left eye and the right eye.

It is preferable that the lens part 20 be installed on at least one of an outer surface and an inner surface of the glass part 10. When the lens part 20 is disposed at the inner surface of the glass part 10, since an image which has passed through the lens part 20 passes through the glass part 10, and different image groups are guided to a left eye and a right eye of a viewer, a stereoscopic image may be presented.

Alternatively, when the lens part 20 is disposed at the outer surface of the glass part 10, since an image which has passed through the glass part 10 passes through the lens part 20, and different image groups are guided to the left eye and the right eye of the viewer, a stereoscopic image may be presented.

The panel part 30 may be formed in various shapes within the technical idea in which the glass part 10 is mounted on the panel part 30. The panel part 30 according to an embodiment is formed in a curved shape along the glass part 10, which has a curved shape, and light is transmitted therethrough.

As illustrated in FIGS. 1 and 2, the rolling part 40 includes a rolling body 42 formed in a cylindrical shape and configured to have the coating material 60 applied on an outer portion thereof and a rotation support shaft 44 configured to protrude toward both sides of the rolling body 42 and rotate together with the rolling body 42.

The rolling body 42 according to an embodiment is formed of a material including a metal, and the coating material 60 is evenly applied on the outer portion of the rolling body 42. A supply part 65 is installed outside the rolling body 42, and the coating material 60, which is sprayed through the supply part 65, is evenly applied to the outer portion of the rolling body 42 which rotates.

Since the rotation support shaft 44 extending toward the both sides of the rolling body 42 is connected to a separate driving device, the rotation support shaft 44 is controlled to rotate at a predetermined revolution speed.

A guide rotation part 50 is installed to be rotatable at a position facing the rolling body 42. The guide rotation part 50 may be formed in various shapes within the technical idea in which the glass part 10 is seated on an outer portion of the guide rotation part 50. The guide rotation part 50 according to an embodiment is formed in a cylindrical shape like the rolling part 40 and is rotated by a control signal from a controller.

The rolling part 40 and the guide rotation part 50 are formed in cylindrical shapes having different diameters, and rotation shafts of the rolling part 40 and the guide rotation part 50 are installed to be parallel to each other. In addition, since the guide rotation part 50 rotates in a direction opposite to the rolling body 42, the rolling part 40 and the guide rotation part 50 rotate while being engaged with each other. For example, when the guide rotation part 50 rotates counterclockwise, the rolling part 40 rotates clockwise.

The supply part 65 is installed outside the rolling part 40, and the coating material 60 sprayed from the supply part 65 is evenly applied on the outer portion of the rolling body 42. Therefore, the lens part 20 is formed at the side of the glass part 10 as the coating material 60, which is applied on the outer portion of the rolling part 40 which is installed to be rotatable, comes in contact with the side of the glass part 10.

As illustrated in FIG. 3, while the coating material 60 is coated on the side of the glass part 10, a hardening part 70 is installed at a position spaced apart from the glass part 10 in order to harden the coating material 60. Therefore, the lens part 20 is formed at the side of the glass part 10.

Hereinafter, an operational state of the curved stereoscopic image display device 1 and manufacturing method thereof according to an embodiment of the present invention will be described in detail with reference to the accompanying drawings.

FIG. 6 is a flowchart illustrating a manufacturing method of the curved stereoscopic image display device 1 according to an embodiment of the present invention.

As illustrated in FIGS. 1 and 6, the manufacturing method of the curved stereoscopic image display device 1 according to an embodiment of the present invention includes a first forming operation of applying the coating material 60 to the outer portion of the rolling part which rotates (S10).

While the rolling part rotates, the coating material 60 is sprayed through the supply part 65 and evenly applied on the outer portion of the rolling body 42 of the rolling part.

As illustrated in FIGS. 2 and 6, the manufacturing method includes a rotating operation of installing the glass part 10 at a position facing the rolling part and rotating the glass part 10 in a direction opposite to a rotating direction of the rolling part (S20).

In this case, the glass part 10 is mounted on an outer portion of the guide rotation part 50 which has a cylindrical shape, rotates together with the guide rotation part 50, and comes in contact with the outer portion of the rolling part. Therefore, when the glass part 10 is mounted on the outer portion of the guide rotation part 50 and the guide rotation part 50 is rotated, the glass part 10 rotates together with the guide rotation part 50. In this case, since the glass part 10 is in contact with the outer portion of the rolling body 42 while rotating, the rolling body 42 and the guide rotation part 50 rotate in opposite directions.

The manufacturing method includes a second forming operation of adhering the coating material 60 to the glass part 10 which is in contact with the outer portion of the rolling part while rotating (S30).

Since the glass part 10 is in contact with the coating material 60 adhered to the outer portion of the rolling body 42 while rotating, the coating material 60 is adhered to a convex side of the glass part 10.

As illustrated in FIGS. 3 and 6, the manufacturing method includes a hardening operation of hardening the coating material 60 on the side of the glass part 10 (S40).

The hardening part 70 is operated while the coating material 60 is coated on the side of the glass part 10 in order to irradiate the glass part 10 with rays. The coating material 60 is hardened due to being irradiated with rays, and then the lens part 20 is formed. Therefore, the glass part 10 and the lens part 20 are fixed while being bonded to each other.

In the hardening operation according to an embodiment, the coating material 60 at the side of the glass part 10 is hardened due to being irradiated with UV rays, and then the lens part 20 is formed.

Alternatively, any hardening method used in hardening raw materials may be used in place of UV hardening in the hardening operation according to embodiments of the present invention.

As illustrated in FIGS. 4 to 6, the manufacturing method includes an assembly operation of assembling the glass part 10 to the panel part 30 while the lens part 20 is formed at the side of the glass part 10 (S50).

Since the glass part 10 according to an embodiment forms a curved surface, an image is transmitted through the glass part 10, and the panel part 30 on which the glass part 10 is mounted is also formed in a curved shape, the glass part 10 including the lens part 20 is easily mounted on the panel part 30.

According to embodiments of the present invention, since, as described above, the lens part 20 is formed at the side of the curved glass part 10 and then the curved lens part 20 is coupled to the curved panel part 30, a production process is shortened, and thus productivity can be increased.

Although the present invention has been disclosed in the form of preferred embodiments and variations thereon, it will be understood that numerous additional modifications and variations could be made thereto without departing from the scope of the invention.

For the sake of clarity, it is to be understood that the use of “a” or “an” throughout this application does not exclude a plurality, and “comprising” does not exclude other steps or elements. The mention of a “unit” or a “module” does not preclude the use of more than one unit or module.

1. A curved stereoscopic image display device comprising:
a glass part configured to form a curved surface and through which an image is transmitted;
a lens part attached to a side of the glass part and configured to form a lens or a barrier and implement a stereoscopic image; and
a panel part to which the glass part is attached,
wherein the lens part is formed at the side of the glass part as a coating material at an outer portion of a rolling part, which is installed to be rotatable, comes in contact with the side of the glass part.

2. The curved stereoscopic image display device of claim 1, wherein the rolling part includes:
a rolling body formed in a cylindrical shape and configured to have a coating material applied on an outer portion thereof; and
a rotation support shaft configured to protrude toward both sides of the rolling body and rotate together with the rolling body.

3. The curved stereoscopic image display device of claim 2, further comprising a guide rotation part installed to be rotatable at a position facing the rolling body and configured to have the glass part seated on an outer portion thereof,
wherein the guide rotation part rotates in a direction opposite to the rolling body.

4. A manufacturing method of a curved stereoscopic image display device, the manufacturing method comprising:
a first forming operation of applying a coating material to an outer portion of a rolling part which rotates;
a rotating operation of installing a glass part at a position facing the rolling part and rotating the glass part in a direction opposite to a rotating direction of the rolling part;
a second forming operation of adhering the coating material to the glass part which is contact with the outer portion of the rolling part while rotating;
a hardening operation of hardening the coating material on a side of the glass part; and
an assembly operation of assembling the glass part to a panel part while a lens part is formed at the side of the glass part.

5. The manufacturing method of claim 4, wherein the glass part forms a curved surface, and an image is transmitted through the glass part.

6. The manufacturing method of claim 5, wherein, in the rotating operation, the glass part is mounted on an outer portion of a guide rotation part, which is formed in a cylindrical shape, and is in contact with the outer portion of the rolling part while rotating together with the guide rotation part.

7. The manufacturing method of claim 4, wherein, in the hardening operation, the coating material adhered to the glass part is hardened by being irradiated with ultraviolet (UV) rays to form the lens part.
